(19) United States
(12) Patent Application Publication
(10) Pub. No.: US 2005/0078501 A1
(43) Pub. Date: Apr. 14, 2005

(54) Method and arrangement for compensation of a magnetic bias field in a storage layer of a magnetoresistive memory cell

(76) Inventor: Joachim Bangert, Erlangen (DE)

Correspondence Address: SLATER & MATSIL, L.L.P., 17950 PRESTON RD, SUITE 1000, DALLAS, TX, 75252-5793, US

(21) Appl. No.: 10/487,951

(22) PCT Filed: Aug. 26, 2002
(86) PCT No.: PCT/DE02/03120

(30) Foreign Application Priority Data
Aug. 31, 2001 (DE) 101 42 594.5

(51) Int. Cl. G11C 11/00

(52) U.S. Cl. 365/129

(57) ABSTRACT

An arrangement is described for compensation of a magnetic bias field in a storage layer of at least one magnetoresistive memory cell provided in a semiconductor device. In this arrangement, at least one compensation layer that is provided with a magnetization compensates for the bias field in the storage layer. A method is also described for compensation of a magnetic bias field in a storage layer of a magnetoresistive memory cell provided in a semiconductor device. A step is provided for applying a ferromagnetic compensation layer. In another step, a bias field is measured in terms of magnitude and direction. In another step, the bias field is compensated by magnetization of the compensation layer.

### BACKGROUND

1. Field

Embodiments of the present invention relate to arrangements for compensation of a magnetic bias field in a storage layer of a magnetoresistive memory cell provided in a semiconductor device. In addition, the invention relates to methods for compensation of such a bias field.

2. Background

A memory cell based on the magnetoresistance effect conventionally has been realized by a stack of two thin ferromagnetic layers, with an intervening nonferromagnetic isolating layer having a thickness of a plurality of atomic layers. One of the two ferromagnetic layers is composed of a hard-magnetic material, typically a cobalt-iron alloy. With a magnetization which is constant in terms of magnitude and direction, it functions as a reference layer. The second ferromagnetic layer made of a soft-magnetic material, typically a nickel-iron alloy, forming a storage layer. Its magnetization is oriented unidirectionally, or in oppositely directed fashion with respect to the magnetization of the reference layer, corresponding to data content of the memory cell.

When a unit of data is written to the memory cell, the direction of a write current in an address line of the memory cell determines the orientation of the magnetization in the storage layer with respect to the magnetization of the reference layer. The material of the isolating layer is a dielectric in the case of a memory cell configuration based on a tunneling effect (MTJ, magnetic tunnel junction). In this case, the effect underlying the read-out of the memory cell is that the frequency of electrons crossing through the isolating layer (tunnel barrier) is higher in the case of identical orientation of the magnetization of the two ferromagnetic layers than in the case of opposite orientation.

The effect underlying the read-out of the memory cell is thus based on internal properties of the magnetized ferromagnetic layers, but not on a direct interaction of the magnetic fields generated by the two layers. Their interaction, or ferro- and antiferromagnetic coupling, influences the operating behavior of the memory cell. In this case, the term “ferromagnetic coupling” denotes that proportion of the interaction that promotes an orientation of the magnetization of the storage layer parallel to the orientation of the magnetization of the reference layer and inhibits a changeover of the magnetization of the storage layer in a direction opposite to the magnetization of the reference layer. The term “antiferromagnetic coupling” denotes that proportion of the interaction that inhibits a storage layer orientation parallel to the orientation of the magnetization of the reference layer and promotes a changeover of the magnetization direction of the storage layer in a direction opposite to the magnetization direction of the reference layer.

The ferro- and antiferromagnetic couplings between the reference layer and storage layer of one and the same memory cell, but also of adjacent memory cells, make contributions to a magnetic bias field within and outside a semiconductor device having magnetoresistive memory cells. In a storage layer permeated by such a bias field, the bias field effects a shift in the field strengths required for changing over the magnetization direction, the so-called coercive field strengths. This shift requires an asymmetry in the magnetic fields required for writing and thus also in the write currents.

This effect is illustrated by the two illustrations in FIG. 2, which is reduced to a one-dimensional changeover of the storage layer for simplification. In this case, H_{C1} and H_{C2} designate magnitudes of coercive field strengths required for changing over the magnetization between the states M₀ and M₁ in the absence of a bias field, and H_{B} denotes the magnitude of the magnetic bias field.

The upper part of FIG. 2 illustrates the magnetization reversal curve of a storage layer for the case of an absent bias field. The specific coercive field strengths H_{C1} and −H_{C1} are symmetrical with respect to the magnetization axis. The lower part of FIG. 2 illustrates a magnetization curve relative to a magnetic field H(I) generated by the write current I in the case of superposition with a bias field acting oppositely to the magnetic field axis. For such a magnetic field, the magnetization curve appears to be shifted by the magnitude H_{B} counter to the direction of H_{B}.

If the bias field and the magnetization of the storage layer are unidirectional, then a changeover of the magnetization requires a magnetic field whose magnitude results from the sum of the specific coercive field strength of the storage layer and the magnetic field strength of the bias field. In this case, the bias field, given a predetermined maximum write current, reduces reserves with regard to a reliable changeover of the magnetization in the storage layer of the memory cell.

If the bias field is directed oppositely to the magnetization of the storage layer, then a magnetic field having a magnitude corresponding to the magnitude of the specific coercive field strength of the storage layer reduced by the magnitude of the magnetic field strength of the bias field already suffices for changing over the magnetization.

In this case, even smaller magnetic fields may compel a changeover of the magnetization. A reserve with respect to an undesired changeover of the magnetization is thus reduced. Such magnetic fields may be caused on the one hand by extreme interference fields with a source outside the semiconductor device. A second source of such magnetic fields is, for instance, magnetic fields generated by write currents of adjacent memory cells within the semiconductor device.

The ferromagnetic coupling which underlies the bias field in the storage layer is determined by the distance between the two ferromagnetic layers, the thickness of the storage layer, and also the roughness of the layers forming the memory cell.

In this respect, reference is made to L. Néel, Comptes Rendus Acad. Sci. 255, 1676 (1962) and, in particular, formula (1) in A. Anguelouch et al., Two-dimensional magnetic switching of micron-size films in magnetic tunnel junctions, Applied Physics Letters, Vol. 76, No. 5, 2000.

In this case, the orientation of the bias field is not necessarily effected in a direction parallel to the orientation of the magnetic fields generated by the write currents, but rather may also have a component which is orthogonal thereto and parallel to the storage layer. In this respect, reference is made in particular to FIG. 2a in A. Anguelouch et al., Two-dimensional magnetic switching of micron-size films in magnetic tunnel junctions, Applied Physics Letters, Vol. 76, No. 5, 2000. The physical causes of this effect are not completely known, but the bias field does not change in terms of magnitude and direction during a lifetime of the memory cell.

In particular, the roughness of the layers yields variable and at the same time difficult-to-predict proportions with respect to the bias field. In this case, the roughness contribution varies between semiconductor devices, even of identical designs, which are produced from different wafers, while it is similar in the case of semiconductor devices which are produced from the same wafer.

FIG. 3 illustrates a diagrammatic cross section through a magnetoresistive memory cell. An isolating layer 2 lies between a reference layer 3 and a storage layer 1. Dividing the reference layer 3 into a lower and an upper reference sublayer 3a, 3c with a nonmagnetic intermediate layer 3b produces a magnetic leakage field, which may produce an antiferromagnetic coupling indicated by the arrow 5. The causes of the ferromagnetic coupling, that is to say the roughness of the layers, and also the thickness of isolating layer and storage layer, are indicated by the arrow 4.

In order to reduce the bias field, at the present time attempts are being made, on the one hand, to reduce the ferromagnetic coupling. On the other hand, attempts are being made to set the antiferromagnetic coupling toward a compensation of the bias field.

A reduction of the ferromagnetic coupling by using a thicker storage layer is confronted with the obstacle of the larger switching currents which are then necessary for changing over the magnetization. Equally, the distance between the ferromagnetic layers is prescribed by the requirements made of the electrical resistance of the memory cell and by thermodynamic requirements.

Limits are imposed on compensation by means of the antiferromagnetic coupling since the latter exhibits a stable behavior only given low net moment. For a maximum effect, one of the reference sublayers would have to be dispensed with, as a result of which the stability of the reference layer would also be impaired. Furthermore, it cannot be used to effect compensation of a ferromagnetic coupling which is brought about for instance as a result of magnetorestriction during a patterning operation of the memory cell or the semiconductor device and is rotated with respect to the magnetization direction of the storage layer. Furthermore, the antiferromagnetic coupling is unsuitable, in the case of semiconductor devices produced from different wafers, for compensating for contributions of the ferromagnetic coupling—brought about by the roughness of the layers—which regularly deviate from one another.

### SUMMARY

An arrangement is disclosed that enables a compensation of a bias field in the storage layer of a magnetoresistive memory cell provided in a semiconductor device and in which the geometry of the memory cell remains unchanged. Methods also are obtained that enable said compensation to be obtained.

An arrangement is disclosed for compensation of a magnetic bias field in a storage layer of at least one magnetoresistive memory cell provided in a semiconductor device. In this arrangement, at least one compensation layer is provided with a magnetization that compensates for the bias field in the storage layer.

A method is described for compensation of a magnetic bias field in a storage layer of a magnetoresistive memory cell provided in a semiconductor device. A step is provided for applying a ferromagnetic compensation layer. In another step, a bias field is measured in terms of magnitude and direction. In another step, the bias field is compensated by magnetization of the compensation layer.

Another method also is described for compensation of a magnetic bias field in a storage layer of a magnetoresistive memory cell provided in a semiconductor device. A bias field is measured in terms of magnitude and direction. The bias field is compensated by application of a compensation layer, which has a magnetization that compensates for the bias field in the storage layer.

The invention is explained in more detail below with reference to the drawings, the same reference symbols being used for mutually corresponding components.

### BRIEF DESCRIPTION OF THE DRAWING

FIG. 1 is a diagrammatic illustration of an exemplary arrangement according to a first and a second exemplary embodiment of the invention,

FIG. 2 is a simplified illustration of the magnetization reversal curve of a storage layer respectively in the absence of a bias field and with an effective bias field, and

FIG. 3 is a diagrammatic illustration of a magnetoresistive memory cell.

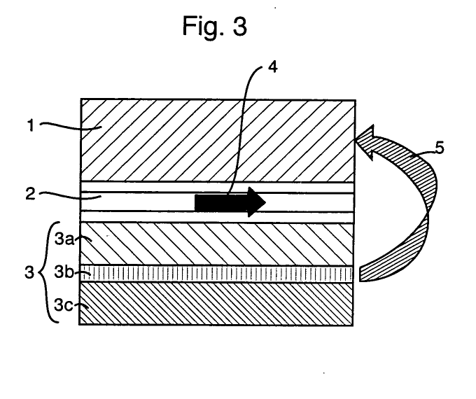

FIGS. 2 and 3 have already been explained in the introduction.

### DETAILED DESCRIPTION OF EXEMPLARY EMBODIMENTS

The following reference symbols are used consistently in the description of the figures as described in the background and as set forth herein:
M Magnetization
H(I) Magnetic field strength of a magnetic field generated by a write current I
H_{C1} Magnitude of a specific coercive field strength
M₀ First magnetization
M₁ Second magnetization
H_{B} Magnitude of the magnetic field strength of the bias field
1 Storage layer
2 Isolating layer
3 Reference layer
3a Upper reference sublayer
3b Intermediate layer
3c Lower reference sublayer
4 Representation of the ferromagnetic coupling
5 Representation of the antiferromagnetic coupling
6 Memory cell
7 Semiconductor device
8 Housing
9 Compensation layer within the semiconductor device
10 Compensation layer outside the semiconductor device
11 Passivation layer

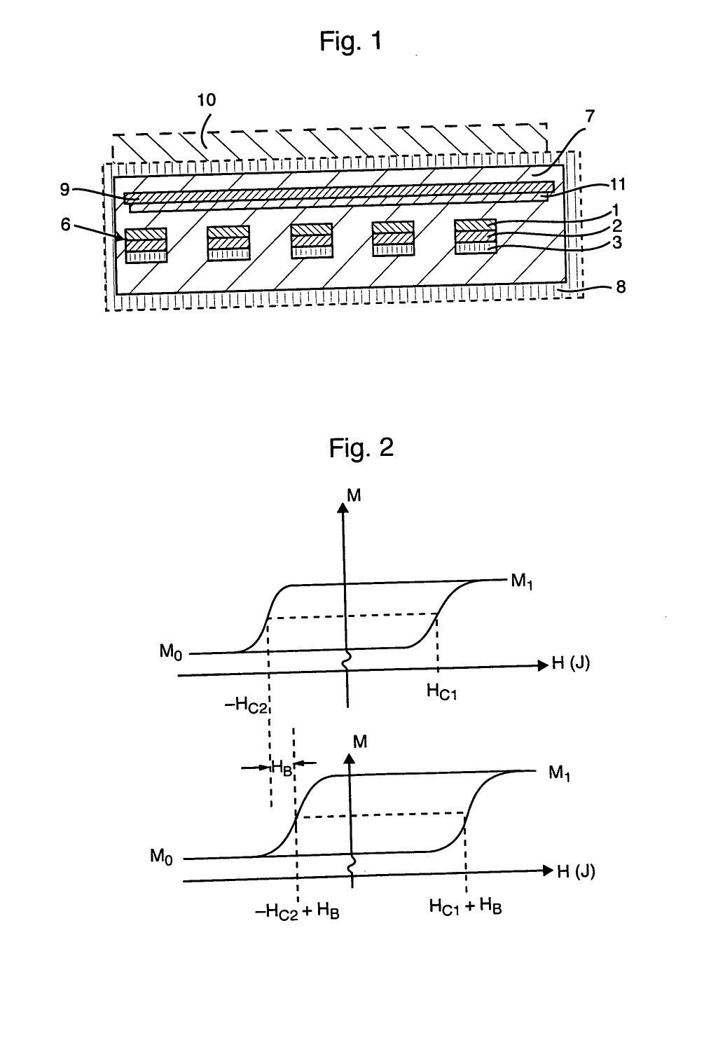

FIG. 1 illustrates a simplified cross-section through a semiconductor device 7 having magnetoresistive memory cells 6, with the cross-section not being true to scale and being restricted to the illustration of certain features that are considered as being generally more significant with regard to the invention.

The memory cells 6 are in each case constructed from storage, isolating and reference layers 1, 2, 3 and, in the example illustrated, are arranged in a single layer of the semiconductor device 7. A passivation layer 11 is applied parallel to a memory cell layer formed from the memory cells 6.

Ferromagnetic coupling between the reference and storage layers 3, 1 of the memory cells 6 gives rise to a magnetic bias field.

The components illustrated by broken lines are omitted for a first exemplary embodiment with a compensation layer 9 provided within the semiconductor device 7. In the first exemplary embodiment, the compensation layer 9 is applied parallel to the storage layers 1 in a manner isolated from the memory cells 6 by a passivation layer 11 and may be magnetized in such a way that the magnetic field of the magnetization compensates for the magnetic bias field in the storage layers 1. In order to obtain a magnetic field that is generated by the magnetization of the compensation layer 9 and is as far as possible identical in terms of magnitude and direction in all the storage layers 1 of the semiconductor device 7, the compensation layer 9 preferably covers an entire cross-sectional area of the semiconductor device 7.

A second exemplary embodiment also comprises components illustrated by broken lines and has a compensation layer 10 provided outside the semiconductor device 7 and a housing 8, which at least partially surrounds the semiconductor device 7, the compensation layer 9 provided within the semiconductor device 7 being obviated.

For the reasons mentioned above, the compensation layer 10 applied outside the semiconductor device is also preferably applied parallel to the storage layers 1 and preferably covers at least an entire surface parallel to the storage layers 1.

Thus, in the case of an arrangement of the type according to embodiments of the invention, a bias field which takes effect in a storage layer of a magnetoresistive memory cell situated in a semiconductor device is compensated for by means of a magnetostatic leakage field (compensation field hereinafter) of at least one suitably magnetized compensation layer.

The compensation layer may be applied outside and/or within the semiconductor device.

If a compensation layer is applied within a semiconductor device, then this is preferably done at the wafer level by means of the technologies that are customary for the processing of a wafer and with the materials which are used in the fabrication of the memory cells. The magnetic properties of such a compensation layer can be influenced by means of a patterning of the compensation layer.

Within the semiconductor device, the compensation layer, for instance isolated by means of an SiO₂ layer, may be applied below a memory cell layer having the memory cells.

In the case of semiconductor devices having a plurality of memory cell layers, each memory cell layer may in each case be assigned at least one compensation layer which is magnetized toward the specific requirements of the respective memory cell layer. In this case, memory cell and compensation layers alternate in the layer construction of the semiconductor device. In a preferred manner, the compensation layer is applied within the semiconductor device on a first passivation following the memory cell layer.

If the compensation layer is applied during or after a process of housing the semiconductor device, then in this context it is deemed to be a compensation layer outside the semiconductor device.

Such a solution is the use of housings made of a ferromagnetic material or the positioning of the semiconductor device on a suitable carrier.

A preferred embodiment of the arrangement for a compensation layer applied outside the semiconductor device is a magnetizable lamina or a film of this type, preferably applied on at least one surface of the semiconductor device which is parallel to the storage layer. What is of crucial importance in this case is that at least one component of the magnetic field runs parallel to the storage layer.

In any event, it is also possible to use an arrangement provided for shielding the semiconductor device against external fields as compensation layer, or else the compensation layer as shielding of the semiconductor device.

In order to generate a compensation field which is homogeneous over all the memory cells, the compensation layer is preferably applied over an entire cross-sectional area of the semiconductor device which is parallel to the storage layers.

A subsequent patterning of the compensation layer enables the fine adjustment of the compensation field. Before the compensation field is adjusted, however, it is necessary to determine it.

The bias field is preferably measured in a test mode of the semiconductor device by means of a measuring apparatus. In this case, the measuring apparatus controls two magnetic measurement fields of variable strength which are parallel to the storage layer and orthogonal with respect to one another. Depending on said measurement fields, a magnetic-field-dependent, typical characteristic value (measurement variable hereinafter) of the memory cell, for instance an electrical resistance of the memory cell, is determined and transmitted to an external test device. In this case, the measurement fields are generated in a suitable manner by currents in interconnects of the semiconductor device which are specially fashioned for this purpose, or with the aid of the existing connecting lines of the memory cell.

The relevant interconnects may be routed toward the outside via connections in the same way as a measuring section for measuring the measurement variable at the semiconductor device. In this case, the measurement fields are controlled and/or the measurement variable is determined by means of a measuring apparatus outside the semiconductor device.

In a preferred manner, the measuring apparatus is at least partially integrated into the semiconductor device and has in each case at least one controllable current source, two triangular-waveform generators and a measuring device suitable for the measurement variable. A measurement operation is only initiated externally and then the measured values for the measurement variable are transmitted toward the outside.

In this case, the measured memory cell may be one of the functional memory cells of the semiconductor device, a reference memory cell or a memory cell provided specifically for this method. Data obtained are used to calculate the compensation field in terms of magnitude and direction.

According to a first method, the compensation of the bias field is effected by a compensation layer which has already been applied in or on the semiconductor device subsequently being magnetized in a manner dependent on measured values measured for the bias field.

The compensation layer is magnetized in an external magnetic field whose strength is set in a manner dependent on the initial magnetization curve (initial curve) of the material of the compensation layer in the specified direction and the values determined for the bias field.

The compensation layer is at least partially composed of a hard-magnetic material, which may have a premagnetization. A magnetic field assigned to the premagnetization is superposed on the bias field to be compensated for. Moreover, the magnetization behavior of the compensation layer does not follow the initial curve of the material.

Thus, in the case of a compensation layer which has already been premagnetized, an incorrect value is determined, under certain circumstances, for the field strength of the external magnetic field which magnetizes the compensation layer. The bias field is then compensated for incompletely.

Therefore, in a preferred manner, the bias field is measured again after a first controlled magnetization of the compensation layer. The measured values obtained can be used to deduce the direction and magnitude of the premagnetization of the compensation layer. A new value is thereupon determined for the strength and direction of the external magnetic field which controls the magnetization of the compensation layer, and the compensation layer is magnetized again using such a magnetic field.

In the case of this first method according, the compensation layer may be provided within the semiconductor device or outside the semiconductor device. It may be patterned, as required, for the purpose of fine adjustment. According to a second method, firstly the bias field is measured before a compensation layer which has already been appropriately magnetized is applied.

The bias field is thus measured with the compensation layer absent and in a manner uncorrupted by such a compensation layer, thereby simplifying the method for compensation of the bias field. The compensation is then also preferably effected in a stage of a process for producing the semiconductor device which is no longer followed by a significant heating step which alters the magnetic conditions of the semiconductor device.

On the basis of the transmitted measured values, a prepared compensation layer which is appropriate in terms of magnitude and direction of the bias field, preferably a prepared film with hard-magnetic sections, is applied on the semiconductor device.

In this case, in a first variant, the prepared films are present in the form of a first collection sorted in terms of magnitude and direction of the magnetization and are applied with uniform orientation.

In a second variant, the prepared films are present as a second collection sorted only in terms of the magnitude of the magnetization and are applied to the semiconductor device with an orientation prescribed by the direction of the bias field.

In a particularly preferred manner, the prepared compensation layer, that is to say also the prepared film, has an inscription which identifies the semiconductor device.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. An arrangement for compensation of a magnetic bias field in a storage layer of at least one magnetoresistive memory cell provided in a semiconductor device, comprising:
at least one compensation layer that is provided with a magnetization compensates for the bias field in the storage layer.

2. The arrangement of claim 1, wherein the compensation layer is situated within the semiconductor device.

3. The arrangement of claim 1, wherein the compensation layer is situated outside the semiconductor device.

4. The arrangement of claim 2, wherein the compensation layer is isolated from the memory cell by at least one insulation layer.

5. The arrangement of claim 1, wherein the magnetic field generated by the compensation layer runs parallel to the storage layer and generally extends over the cross-sectional area of the semiconductor device.

6. The arrangement of claim 1, wherein the compensation layer is patterned for fine adjustment.

7. A method for compensation of a magnetic bias field in a storage layer of a magnetoresistive memory cell provided in a semiconductor device, comprising:
applying a ferromagnetic compensation layer;
measuring a bias field in terms of magnitude and direction; and
compensating the bias field by magnetization of the compensation layer.

8. The method as in claim 7, wherein the measurement and compensation of the bias field are repeated at least once in order to preclude an erroneous compensation due to a premagnetization of the compensation layer.

9. The method of claim 7, wherein the compensation layer is applied within the semiconductor device.

10. The method of claim 7, wherein the compensation layer is applied outside the semiconductor device.

11. The method of claim 10, wherein the compensation layer is patterned.

12. A method for compensation of a magnetic bias field in a storage layer of a magnetoresistive memory cell provided in a semiconductor device, comprising:
measuring a bias field in terms of magnitude and direction, and
compensating the bias field by application of a compensation layer, which has a magnetization that compensates for the bias field in the storage layer.

13. The method of claim 12, wherein measured values of a measurement variable that characterizes the magnitude and direction of the magnetic bias field are determined by a measuring apparatus in a test mode of the semiconductor device and are transmitted to a test apparatus.

14. The method of claim 13, wherein the measuring apparatus controls two mutually orthogonal measurement currents parallel to the storage layer, which generate two magnetic measurement fields that are orthogonal to one another, and in that a magnetic-field-dependent characteristic variable of the memory cell is in each case determined for different pairs of values of the measurement fields by means of a measuring device.

15. The method of claim 12, wherein the measuring apparatus is provided at least partially within the semiconductor device.

16. The method of claim 12, wherein the compensation layer is applied as a film with which the semiconductor device is inscribed.
